(19) United States
(12) Patent Application Publication
(10) Pub. No.: US 2025/0318299 A1
(43) Pub. Date: Oct. 9, 2025

(54) IMAGING DEVICE

(71) Applicant: VisEra Technologies Company Ltd., Hsin-Chu City (TW)

(72) Inventors: Kuei-An LIN, Hsin-Chu City (TW); Zong-Ru TU, Hsin-Chu City (TW)

(21) Appl. No.: 18/626,901

(22) Filed: Apr. 4, 2024

(51) Int. Cl. H01L 27/146; H04N 25/704

(52) U.S. Cl. CPC H10F 39/8053; H04N 25/704

(57) ABSTRACT

The present disclosure provides an imaging device. The imaging device includes a substrate and an array of pixels. The substrate has an isolation region. The array of pixels includes a plurality of sensing pixels and a plurality of phase detection auto focus (PDAF) pixels, in which each of the PDAF pixels includes four photoelectric conversion elements, a color filter layer, and a deflection element. The four photoelectric conversion elements are in the substrate and separated by the isolation region of the substrate. The color filter layer is on the four photoelectric conversion elements. The deflection element is inside the color filter layer and partially over the isolation region of the substrate, in which a refractive index of the deflection element is larger than a refractive index of the color filter layer.

### BACKGROUND

### Field of Invention

The present disclosure relates to an imaging device.

### Description of Related Art

In imaging devices, such as the charge-coupled device (CCD), the complementary metal oxide semiconductor (COMS) sensor, or the like, the resolution improves as the pixels shrink to smaller sizes. However, as the size shrinks, the sensing area of the pixel becomes smaller, which leads to a drop in the sensing sensitivity. The drop in the sensing sensitivity causes problems, for example, in accurately determining the phase difference between the sensing elements while performing the phase detection to do the autofocus in the phase detection autofocus (PDAF) pixels. Moreover, the PDAF pixels may require a different compensation to correct the incoming angle of the light than the regular sensing pixels for better sensing quality. Therefore, a novel design of the imaging device to solve the problems is necessary.

### SUMMARY

The present disclosure provides an imaging device. The imaging device includes a substrate and an array of pixels. The substrate has an isolation region. The array of pixels includes a plurality of sensing pixels and a plurality of phase detection auto focus (PDAF) pixels, in which each of the PDAF pixels includes four photoelectric conversion elements, a color filter layer, and a deflection element. The four photoelectric conversion elements are in the substrate and separated by the isolation region of the substrate. The color filter layer is on the four photoelectric conversion elements. The deflection element is inside the color filter layer and partially over the isolation region of the substrate, in which a refractive index of the deflection element is larger than a refractive index of the color filter layer.

In some embodiments, the refractive index of the deflection element is from 1.5 to 2.0.

In some embodiments, a ratio of a number of the PDAF pixels to a number of the sensing pixels in the array of the pixels is from 0.8% to 1.64%.

In some embodiments, from a cross-section view, a height of the deflection element is smaller than ⅓ of a height of the color filter layer.

In some embodiments, the height of the deflection element is from 0.15 μm to 0.3 μm.

In some embodiments, from a top view, an array axis extends from a center of the array of pixels to a short side of the array of pixels and the array axis is parallel to a long side of the array of pixels; and for each of the PDAF pixels from the top view, a first connection line is defined to connect a center of the PDAF pixel to the center of the array of pixels, a position angle is between the array axis and the first connection line, a pixel axis passes the center of the PDAF pixel and is parallel to the array axis, a second connection line is defined to connect centers of two farthest sides of the deflection element, an angle is between the pixel axis and the second connection line, and the angle is equal to 90° minus the position angle.

In some embodiments, from a top view, the array of pixels has a positive X-axis, a positive Y-axis, a negative X-axis, and a negative Y-axis corresponding to a Cartesian coordinate, an origin of the Cartesian coordinate is at a center of the array of pixels, the PDAF pixels include a first PDAF pixel on the positive X-axis, a second PDAF pixel on the positive Y-axis, a third PDAF pixel on the negative X-axis, and a fourth PDAF pixel on the negative Y-axis, and relative to the deflection element of the first PDAF pixel, the deflection element of the second PDAF pixel, the deflection element of the third PDAF pixel, and the deflection element of the fourth PDAF pixel are rotated 90°, 180°, and 270°, respectively.

In some embodiments, the PDAF pixels further include a fifth PDAF pixel on a diagonal line between the positive X-axis and the positive Y-axis, a sixth PDAF pixel on a diagonal line between the positive Y-axis and the negative X-axis, a seventh PDAF pixel on a diagonal line between the negative X-axis and the negative Y-axis, and an eighth PDAF pixel on a diagonal line between the negative Y-axis and the positive X-axis, and relative to the deflection element of the first PDAF pixel, the deflection element of the fifth PDAF pixel, the deflection element of the sixth PDAF pixel, the deflection element of the seventh PDAF pixel, and the deflection element of the eighth PDAF pixel are rotated 45°, 135°, 225°, and 315°, respectively.

In some embodiments, from a top view, the PDAF pixels include a first PDAF pixel and a second PDAF pixel, the first PDAF pixel is closer to a center of the array of pixels than the second PDAF pixel, a center of the deflection element of the first PDAF pixel shifts from a center of the first PDAF pixel in a direction toward the center of the array of pixels, and a center of the deflection element of the second PDAF pixel shifts from a center of the second PDAF pixel in a direction away from the center of the array of pixels.

In some embodiments, in each of the PDAF pixels from a top view, a shifted distance is between a center of the deflection element and a center of the PDAF pixel, and the shifted distance is equal to X*ND+Y, where X is from 0 to ½ times a length of one of the four photoelectric conversion elements, Y is from − 1/30 to 1/30 times the length of the one of the four photoelectric conversion elements, ND is equal to D/D_{MAX}, D is a distance between the center of the PDAF pixel and a center of the array of pixels, and D_{MAX} is a distance between the center of the array of pixels and an edge of the array of pixels that is farthest away from the center of the array of pixels.

In some embodiments, the length of the one of the four photoelectric conversion elements is from 0.25 μm to 4 μm.

In some embodiments, the deflection element has a rectangle shape from a top view, and the rectangle shape has a long side and a short side that is shorter than the long side.

In some embodiments, the long side is arranged to face a center of the array of pixels from the top view.

In some embodiments, a length of the short side is from 0.1 μm to 0.5 μm, and a length of the long side is from 0.5 μm to 4 μm.

In some embodiments, the deflection element has an arc shape from a top view, and an arc angle of the arc shape is larger than or equal to 90° and is smaller than 180°.

In some embodiments, a concave side of the arc shape is arranged to face a center of the array of pixels from the top view.

In some embodiments, the deflection element includes TiO₂.

In some embodiments, each of the PDAF pixels is surrounded by the sensing pixels, and the deflection element is not configured in the sensing pixels.

In some embodiments, an upper surface of the deflection element is in direct contact with the color filter layer.

In some embodiments, each of the PDAF pixels further includes a light converging element, and in each of the PDAF pixels, a center of the light converging element shifts from a center of the PDAF pixel.

### BRIEF DESCRIPTION OF THE DRAWINGS

The present disclosure can be more fully understood by reading the following detailed description of the embodiment, with reference made to the accompanying drawings.

FIG. 1 is a cross-sectional view of the imaging device according to some embodiments of the present disclosure.

FIG. 2 is a perspective view from the top of the imaging device according to some embodiments of the present disclosure.

FIGS. 3 to 4 are perspective views from the top of the imaging device according to a first embodiment of the present disclosure.

FIG. 5 is a perspective view from the top of one of the PDAF pixels according to the first embodiment of the present disclosure.

FIGS. 6 to 7 are perspective views from the top of the imaging device according to a second embodiment of the present disclosure.

FIG. 8 is a perspective view from the top of one of the PDAF pixels according to the second embodiment of the present disclosure.

### DETAILED DESCRIPTION

To make the description of the present disclosure more detailed and complete, the following provides an illustrative description of the aspects of the implementation and the specific embodiments of the present disclosure. The disclosure is not to limit the implementation to only one form. The embodiments of the present disclosure may be combined or substituted with each other for a beneficial circumstance, and other embodiments may be appended without further explanation.

Spatially relative terms, such as above and below, etc., may be used in the present disclosure to describe the relation of one element or feature to another element or feature in the figures. The spatially relative terms are intended to encompass different orientations of the device in use or operation in addition to the orientation depicted in the figures. For example, the device may be oriented otherwise, e.g., 90 degrees or other orientations. Therefore, the spatially relative terms in the present disclosure can be interpreted correspondingly. In addition, in the present disclosure, unless otherwise stated, the same or similar reference numbers in different figures refer to the same or similar elements formed from the same or similar materials by the same or similar methods.

The terms “about”, “around”, “approximately”, “basically”, “substantially”, and so on used in the present disclosure include the stated values, characteristics, and the range of deviations from that values and characteristics that can be understood by one skilled in the art. For example, taking into account the errors of values and characteristics, the foregoing terms may include the values within one or more standard deviations (e.g., ±5%, ±10%, ±15%, ±20%, or ±30%) of the stated value, or include the deviations from the practical operations of the stated characteristics (e.g., the “substantially parallel” may be close to parallel in practice rather than an ideally perfect parallel). In addition, the acceptable range of deviations may be selected according to the measurements or other properties, and not only one kind of deviation may be applicable to all values and characteristics.

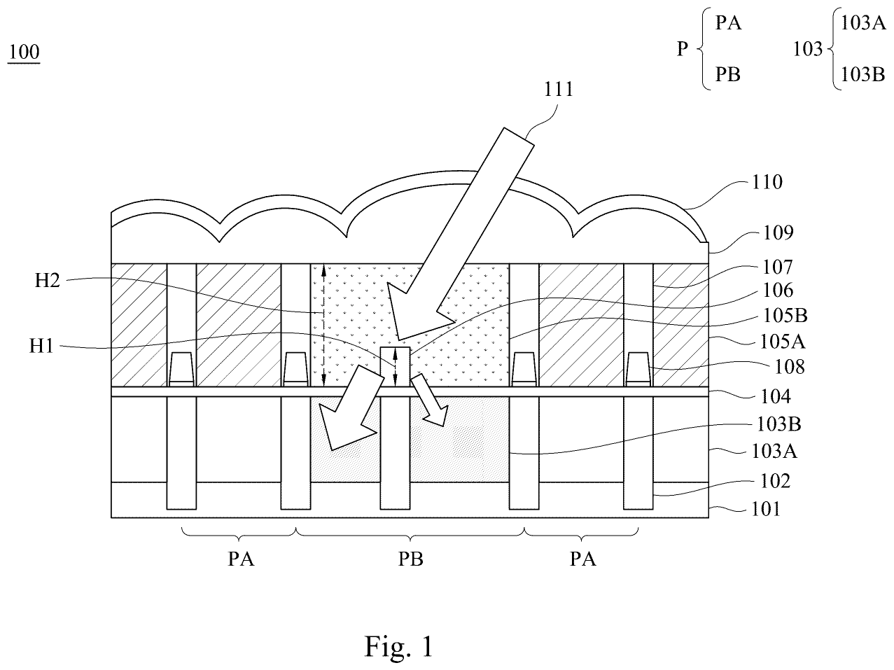

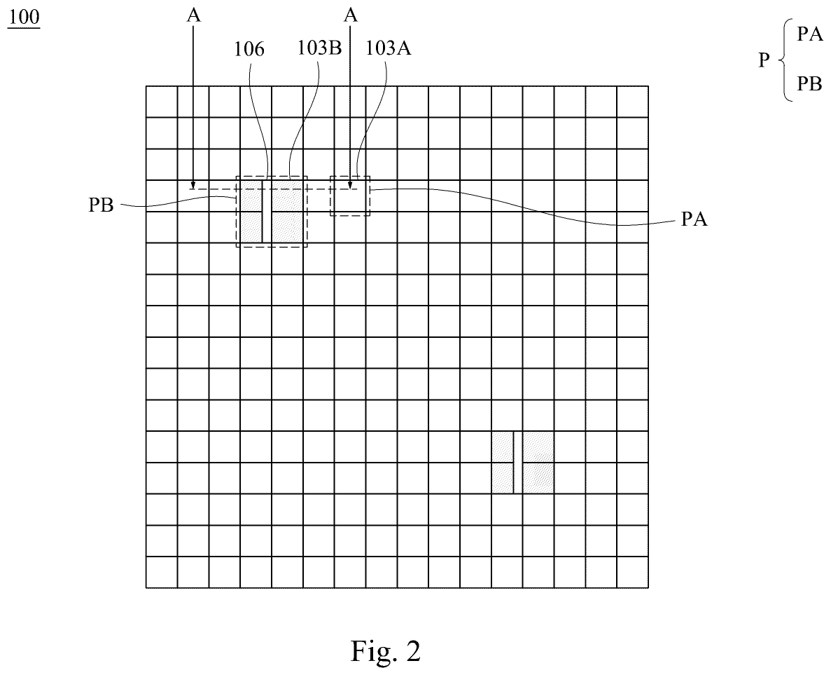

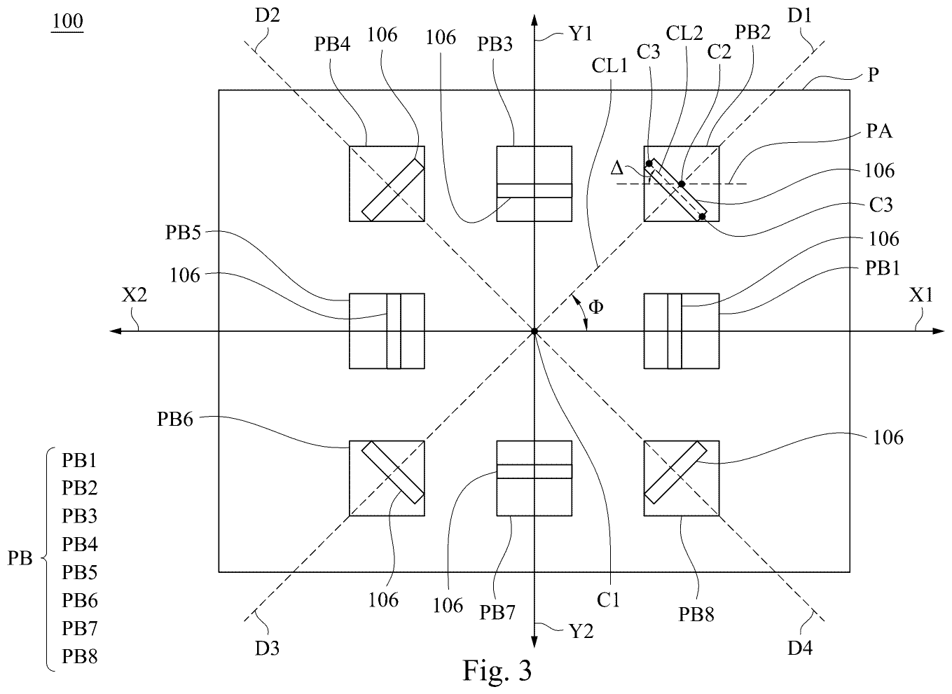

The present disclosure provides an imaging device 100 as shown in FIGS. 1 to 8, in which a cross-sectional view of FIG. 1 is taken from a line A-A shown in a top view of FIG. 2, and FIGS. 3 to 5 and FIGS. 6 to 7 are respectively a first embodiment and a second embodiment of the present disclosure. Specifically, the imaging device 100 includes a substrate 101 and an array of pixels P disposed on the substrate 101. The array of pixels P includes a plurality of sensing pixels PA and a plurality of phase detection auto focus (PDAF) pixels PB, in which each of the PDAF pixels PB includes four photoelectric conversion elements 103B, a color filter layer 105B, and a deflection element 106. The four photoelectric conversion elements 103B are disposed in a substrate 101 and separated by an isolation region 102 of the substrate 101. The color filter layer 105B is disposed continuously on the four photoelectric conversion elements 103B. The deflection element 106 is disposed in the color filter layer 105B and has at least a portion disposed on the isolation region 102. In addition, the refractive index of the deflection element 106 is larger than the refractive index of the color filter layer 105B. The four photoelectric conversion elements 103B of the PDAF pixels PB sense the incoming light with significantly improved sensitivity, and the incoming angle of the light that irradiates the four photoelectric conversion elements 103B of the PDAF pixels PB is redirected by the deflection element 106 to improve the mismatch of the sensing between the PDAF pixels PB and the sensing pixels PA. In this way, the sensitivity of autofocusing and the quality of imaging (e.g., avoiding shading, avoiding color mismatch, increasing sensing intensity etc.) are improved. The imaging device 100 of the present disclosure is described in detail with the following embodiments.

The substrate 101 may be a semiconductor substrate and includes any suitable semiconductor material. In some embodiments, the semiconductor material may include elemental semiconductor materials (e.g., carbon, monocrystalline silicon, polycrystalline silicon, amorphous silicon, germanium, tin, sulfur, selenium, tellurium, or the like), compound semiconductor materials (e.g., silicon carbide, boron nitride, aluminum nitride, gallium nitride, gallium phosphide, gallium arsenide, indium phosphide, indium arsenide, indium antimonide, zinc oxide, or the like), alloy semiconductor materials (e.g., SiGe, AlGaAs, InGaAs, InGaP, AlInAs, GaAsP, AlGaN, InGaN, AlGaInP, or the like), or combinations thereof.

The isolation region 102 of the substrate 101 separates the photoelectric conversion elements 103 disposed in the substrate 101. The isolation region 102 may include any suitable electrically insulating material. In some embodiments, the electrically insulating material may include silicon dioxide, SiON, SiCN, the like, or combinations thereof. In some embodiments, the isolation region 102 is a shallow trench isolation (STI) that is formed by etching a portion of the substrate 101 to form a trench in the substrate 101 and filling the trench with the electrically insulating material.

The array of pixels P is a two-dimensional array of pixels disposed on the substrate 101. Specifically, the array of pixels P includes the sensing pixels PA and the PDAF pixels PB, in which each of the PDAF pixels PB is surrounded by the sensing pixels PA. The sensing pixels PA may be the regular pixels and referred to as normal pixels, and the PDAF pixels PB may perform phase detection towards the incoming light. In the present disclosure, each of the sensing pixels PA includes one photoelectric conversion element 103A and excludes any deflection element 106 disposed on the one photoelectric conversion element 103A, and each of the PDAF pixels PB includes four photoelectric conversion elements 103B and includes one deflection element 106 disposed on the four photoelectric conversion elements 103B. The photoelectric conversion elements 103A and the photoelectric conversion elements 103B are collectively referred to as the photoelectric conversion elements 103 in the present disclosure. The number of the pixels in the array of pixels P may be any suitable number not limited to the number shown in the figures. In some embodiments, a ratio of a number of the PDAF pixels PB to a number of the sensing pixels PA in the array of the pixels P is preferably from 0.8% to 1.64%, for example, 0.8%, 1.01%, 1.22%, 1.43%, or 1.64%. If the ratio is smaller than the foregoing region, the number of the PDAF pixels PB may not be enough to perform the phase detection efficiently. If the ratio is larger than the foregoing region, the total number of the photoelectric conversion elements 103 may not be enough to improve the sensing resolution. Next, the sensing pixels PA and the PDAF pixels PB are described in detail with the following embodiments.

In some embodiments, the photoelectric conversion element 103A in each of the sensing pixels PA is a photodiode to convert the incoming light to an electrical signal. In some embodiments, each of the sensing pixels PA further includes a color filter layer 105A continually covering the photoelectric conversion element 103A. In some embodiments, in each of the sensing pixels PA, the color filter layer 105A continually covers a whole upper surface of the photoelectric conversion element 103A. The color filter layer 105A may filter specific wavelengths of the incoming light according to the type of the photoelectric conversion element 103A disposed below. For example, the color filter layer 105A that transmits a red, green, or blue light may be respectively disposed on the photoelectric conversion element 103A that is sensitive to the red, green, or blue light. Therefore, the sensing pixels PA may be divided into types based on the types of the photoelectric conversion elements 103A. For example, the sensing pixel PA including the photoelectric conversion element 103A that is sensitive to the red, green, are blue light may be respectively referred to as a red, green, or blue sensing pixel PA. In some embodiments, an intermediate layer 104 may be disposed between the photoelectric conversion element 103A and the color filter layer 105A. In some embodiments, the intermediate layer 104 may be a dielectric layer and may include one or more suitable layers. In some embodiments, the dielectric layer may include HfO₂, HfTaO, HfTiO, HfZrO, Ta₂O₅, SiO₂, Si₃N₄, SiON, the like, or combinations thereof.

In some embodiments, the four photoelectric conversion elements 103B in each of the PDAF pixels PB are photodiodes to convert the incoming light to electrical signals. In some embodiments, the four photoelectric conversion elements 103B may be arranged into a 2×2 array in each of the PDAF pixels PB. In some embodiments, each of the PDAF pixels PB further includes a color filter layer 105B continually covering the four photoelectric conversion elements 103B. In some embodiments, in each of the PDAF pixels PB, the color filter layer 105B continually covers the whole upper surfaces of the four photoelectric conversion elements 103B. The color filter layer 105B may filter specific wavelengths of the incoming light according to the types of the four photoelectric conversion elements 103B disposed below. For example, the color filter layer 105B that transmits a red, green, or blue light may be respectively disposed on the four photoelectric conversion elements 103B that are sensitive to the red, green, or blue light. Therefore, the PDAF pixels PB may be divided into types based on the types of the four photoelectric conversion elements 103B. For example, the PDAF pixel PB including the four photoelectric conversion elements 103B that are sensitive to the red, green, or blue light may be respectively referred to as a red, green, or blue PDAF pixels PB. In some embodiments, the types of the four photoelectric conversion elements 103B and the type of the photoelectric conversion element 103A disposed next to such four photoelectric conversion elements 103B may be the same. In some embodiments, the intermediate layer 104 described above may also be disposed between the four photoelectric conversion elements 103B and the color filter layer 105B. In some embodiments, the size of the photoelectric conversion element 103B may be substantially the same as the size of the photoelectric conversion element 103A.

Each of the PDAF pixels PB includes a deflection element 106 disposed in the color filter layer 105B, and the deflection element 106 has at least a portion disposed on the isolation region 102 of the substrate 101. The deflection element 106 may separate the incoming light 111 and redistribute the intensity of the incoming light 111 into different ones of the four photoelectric conversion elements 103B. Therefore, the ratio of the sensing intensity of one of the four photoelectric conversion elements 103B to the sensing intensity of another one of the four photoelectric conversion elements 103B may be enhanced to increase the sensing sensitivity of the PDAF pixels PB. In some embodiments, an upper surface of the deflection element 106 is in direct contact with the color filter layer 105B. In some embodiments, the refractive index of the deflection element 106 is larger than the refractive index of the color filter layer 105B. In some embodiments, the refractive index of the deflection element 106 is preferably from 1.5 to 2.0, for example, 1.5, 1.6, 1.7, 1.8, 1.9, or 2.0. In some embodiments, the refractive index of the color filter layer 105B is preferably from 1.4 to 1.8, for example, 1.4, 1.5, 1.6, 1.7, or 1.8. In some embodiments, the deflection element 106 preferably includes TiO₂. In some embodiments, from a cross-section view, a height H1 of the deflection element 106 is smaller than ⅓ of a height H2 of the color filter layer 105B. In some embodiments, the height H1 of the deflection element 106 is preferably from 0.15 μm to 0.3 μm, for example, 0.15 μm, 0.175 μm, 0.2 μm, 0.225 μm, 0.25 μm, 0.275 μm, or 0.3 μm. In some embodiments, the height H2 of the color filter layer 105B is preferably from 0.5 μm to 1 μm, for example, 0.5 μm, 0.6 μm, 0.7 μm, 0.8 μm, 0.9 μm, or 1 μm. In some embodiments, the shape of the deflection element 106 is not limited to the shape as shown in FIGS. 1 to 2, and from a top view, the deflection element 106 may has a rectangle shape or an arc shape respectively shown in the first embodiment and the second embodiment described below.

In some embodiments, a separation grid 107 may be disposed between the color filter layers 105A, the color filter layers 105B, and the combination thereof to separate the color filter layers 105A, the color filter layers 105B, and the combination thereof. In some embodiments, the separation grid 107 is disposed between the sensing pixels PA, the PDAF pixels, and the combination thereof. In some embodiments, the refractive index of the separation grid 107 is smaller than the refractive indexes of the color filter layers 105A and the color filter layers 105B. In some embodiments, the separation grid 107 is transparent. In some embodiments, the separation grid 107 includes a dielectric material.

In some embodiments, a light shielding layer 108 may be disposed between the color filter layers 105A, the color filter layers 105B, and the combination thereof. In some embodiments, the light shielding layer 108 may be disposed between the sensing pixels PA, the PDAF pixels, and the combination thereof. In some embodiments, the light shielding layer 108 is aligned with the separation grid 107, and the separation grid 107 is disposed on the light shielding layer 108. When an incoming light is majorly irradiating one of the photoelectric conversion elements 103, the light shielding layer 108 may shield the incoming light to irradiate a neighboring one of the photoelectric conversion elements 103 in case the incoming light has a too large angle of incidence. Therefore, the sensing accuracy and the imaging quality of the imaging device 100 may be improved. In some embodiments, the light shielding layer 108 includes metal, metal oxide, metal nitride, the like, or combinations thereof.

In some embodiments, light converging elements 109 may be disposed on the color filter layers 105A and the color filter layers 105B to converge the light irradiating the photoelectric conversion elements 103. In some embodiments, each of the light converging elements 109 corresponds to one of the sensing pixels PA or the PDAF pixels PB. In some embodiments, each of the light converging elements 109 is a convex lens having an upper surface protruding away from the photoelectric conversion elements 103. In some embodiments, the center of the light converging element 109 may align with the center or shift away from the center of the corresponding one of the sensing pixels PA or the PDAF pixels PB, depending on the position of the corresponding one of the sensing pixels PA or the PDAF pixels PB in the array of pixels P. For example, the center of the light converging element 109 may align with the center of the corresponding one of the sensing pixels PA or the PDAF pixels PB when the corresponding one of the sensing pixels PA or the PDAF pixels PB is substantially at the center of the array of pixels P, and the center of the light converging element 109 may shift away from the center of the corresponding one of the sensing pixels PA or the PDAF pixels PB when the corresponding one of the sensing pixels PA or the PDAF pixels PB is substantially away from the center of the array of pixels P. In some embodiments, a shifting distance between the center of the light converging element 109 and the center of the corresponding one of the sensing pixels PA or the PDAF pixels PB increases as the distance between the center of the corresponding one of the sensing pixels PA or the PDAF pixels PB and the center of the array of pixels P increases. In some embodiments, an anti-reflective coating layer 110 may be disposed on the light converging elements 109.

Next, different aspects of the deflection element 106, referring to FIGS. 3 to 8, are described in detail. It should be noted that some elements, such as the sensing pixels PA, are not drawn in FIGS. 3 to 8 for a better understanding of the deflection elements 106.

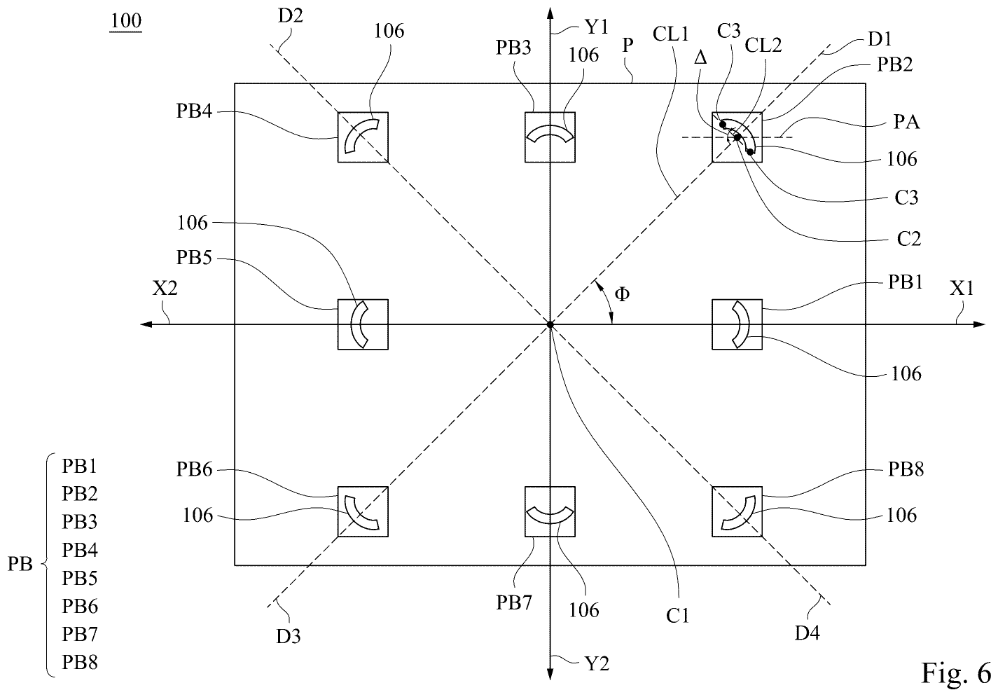

In some embodiments, the deflection elements 106 disposed in different positions of the array of pixels P may be rotated in different angles respectively to each other from a top view, such that the deflection elements 106 may align differently in the array of pixels P, as shown in FIGS. 3 and 6. For a better definition of the positions of the deflection elements 106 in the array of pixels P, the array of pixels P may be defined to have array axes including a positive X-axis X1, a positive Y-axis Y1, a negative X-axis X2, and a negative Y-axis Y2 corresponding to a Cartesian coordinate from a top view, and an origin of the Cartesian coordinate is at the center C1 of the array of pixels P. In addition, a diagonal line D1 is in a first quadrant of the Cartesian coordinate and an angle between the diagonal line D1 and the positive X-axis X1 and an angle between the diagonal line D1 and the positive Y-axis Y1 are the same, a diagonal line D2 is in a second quadrant of the Cartesian coordinate and an angle between the diagonal line D2 and the positive Y-axis Y1 and an angle between the diagonal line D2 and the negative X-axis X2 are the same, a diagonal line D3 is in a third quadrant of the Cartesian coordinate and an angle between the diagonal line D3 and the negative X-axis X2 and an angle between the diagonal line D3 and the negative Y-axis Y2 are the same, a diagonal line D4 is in a fourth quadrant of the Cartesian coordinate and an angle between the diagonal line D4 and the positive X-axis X1 and an angle between the diagonal line D4 and the negative Y-axis Y2 are the same. In the embodiment that the array of pixels P has a rectangle shape from a top view, the rectangle shape of the array of pixels P has a long side and a short side that is shorter than the long side, and the positive X-axis X1 is defined to extend from the center C1 of the array of pixels P to the short side of the array of pixels P and the positive X-axis X1 is parallel to the long side of the array of pixels P. For each of the PDAF pixels PB from a top view, a first connection line CL1 is defined to connect the center C2 of the PDAF pixel PB to the center C1 of the array of pixels P, so a position angle ϕ is between the positive X-axis X1 and the first connection line CL1. For each of the PDAF pixels PB from a top view, a pixel axis PA is defined to pass the center C2 of the PDAF pixel PB and be parallel to the positive X-axis X1, and a second connection line CL2 is defined to connect centers C3 of two farthest sides of the deflection element 106, so an angle Δ is between the pixel axis PA and the second connection line CL2. In some embodiments, the angle Δ is substantially equal to 90° minus the position angle ϕ, so depending on the positions of the deflection elements 106 in the array of pixels P, angles Δ of the deflection elements 106 may be different. By having different angles Δ of the deflection elements 106, the incoming light may effectively irradiate the photoelectric conversion elements 103 and the mismatch of the sensing between the PDAF pixels PB and the sensing pixels PA may be corrected for a better sensing quality.

In some embodiments, the PDAF pixels PB may include a PDAF pixel PB1 on the positive X-axis X1, a PDAF pixel PB2 on the diagonal line D1, a PDAF pixel PB3 on the positive Y-axis Y1, a PDAF pixel PB4 on the diagonal line D2, a PDAF pixel PB5 on the negative X-axis X2, a PDAF pixel PB6 on the diagonal line D3, a PDAF pixel PB7 on the negative Y-axis Y2, an PDAF pixel PB8 on the diagonal line D4, or combinations thereof, as shown in FIGS. 3 and 6. In these embodiments, relative to the deflection element 106 of the PDAF pixel PB1, the deflection element 106 of the PDAF pixel PB2, the deflection element 106 of the PDAF pixel PB3, the deflection element 106 of the PDAF pixel PB4, the deflection element 106 of the PDAF pixel PB5, the deflection element 106 of the PDAF pixel PB6, the deflection element 106 of the PDAF pixel PB7, and the deflection element 106 of the PDAF pixel PB8 are rotated 45°, 90°, 135°, 180°, 225°, 270°, and 315°, respectively. In some embodiments, the position angle ϕ of the PDAF pixel PB1, the position angle ϕ of the PDAF pixel PB2, the position angle ϕ of the PDAF pixel PB3, the position angle ϕ of the PDAF pixel PB4, the position angle ϕ of the PDAF pixel PB5, the position angle ϕ of the PDAF pixel PB6, the position angle ϕ of the PDAF pixel PB7, and the position angle ϕ of the PDAF pixel PB8 are respectively 0°, 45°, 90°, 135°, 180°, 225°, 270°, and 315°, so the angle Δ of the deflection elements 106 of the PDAF pixel PB1, the angle Δ of the deflection elements 106 of the PDAF pixel PB2, the angle Δ of the deflection elements 106 of the PDAF pixel PB3, the angle Δ of the deflection elements 106 of the PDAF pixel PB4, the angle Δ of the deflection elements 106 of the PDAF pixel PB5, the angle Δ of the deflection elements 106 of the PDAF pixel PB6, the angle Δ of the deflection elements 106 of the PDAF pixel PB7, and the angle Δ of the deflection elements 106 of the PDAF pixel PB8 are respectively 90°, 45°, 0°, −45°, −90°, −135°, −180°, and −225°. In some embodiments, the deflection elements 106 are rotated such that the deflection elements 106 are arranged in a centrosymmetric pattern, and the center of the centrosymmetric pattern corresponds to the center C1 of the array of pixels P.

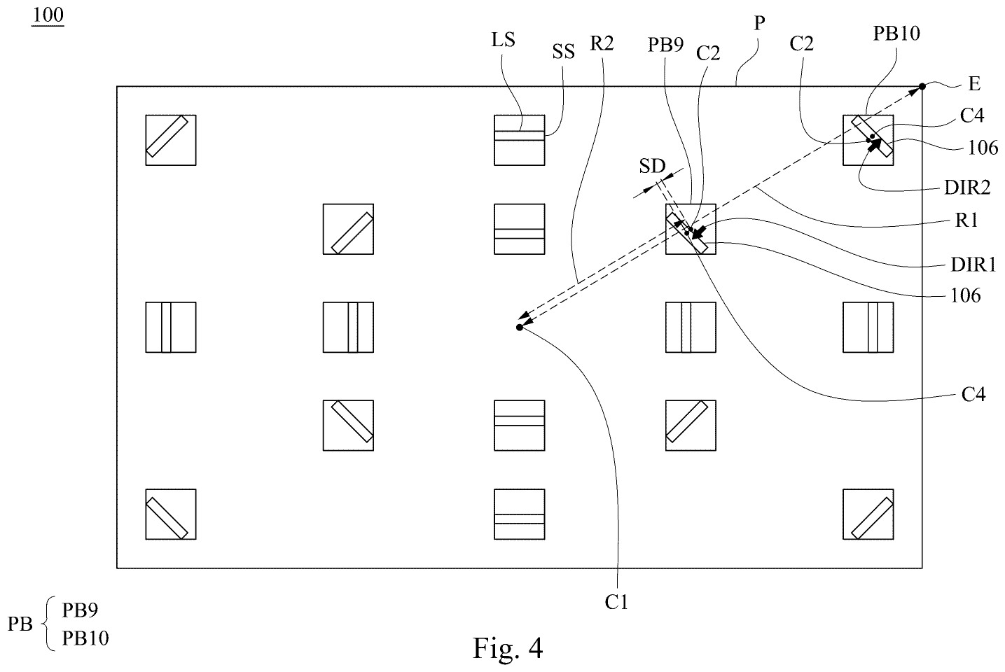

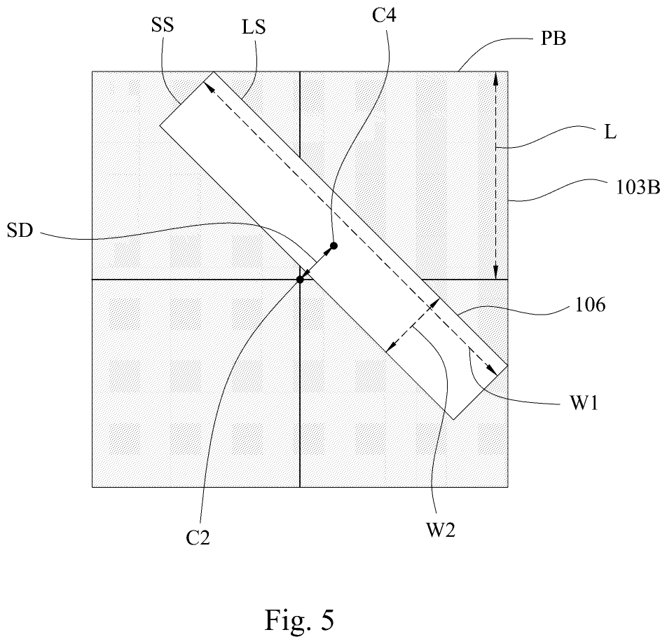

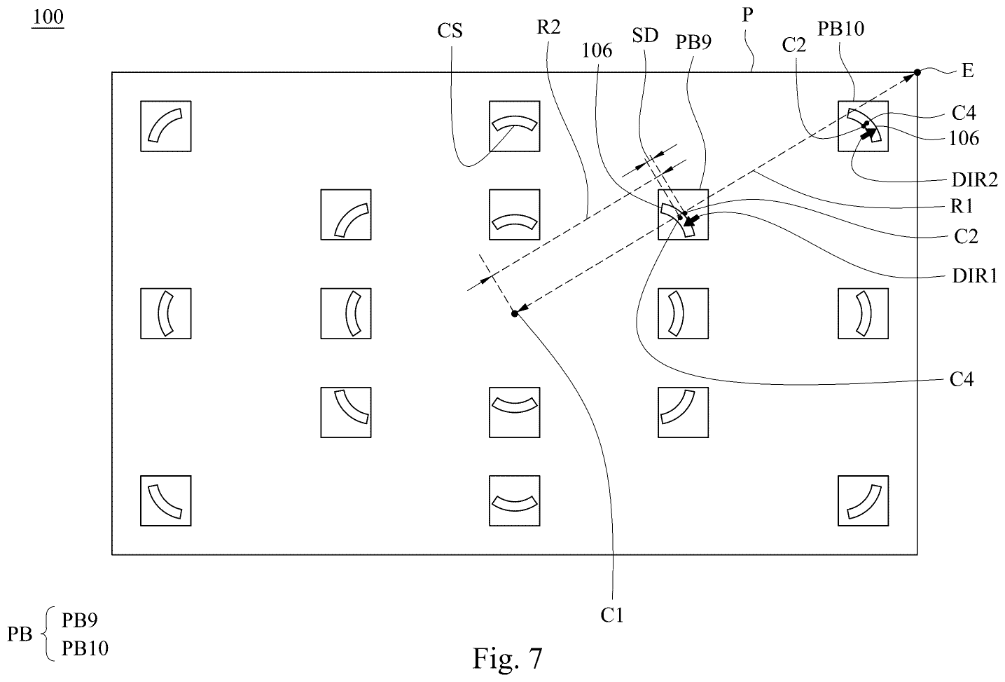

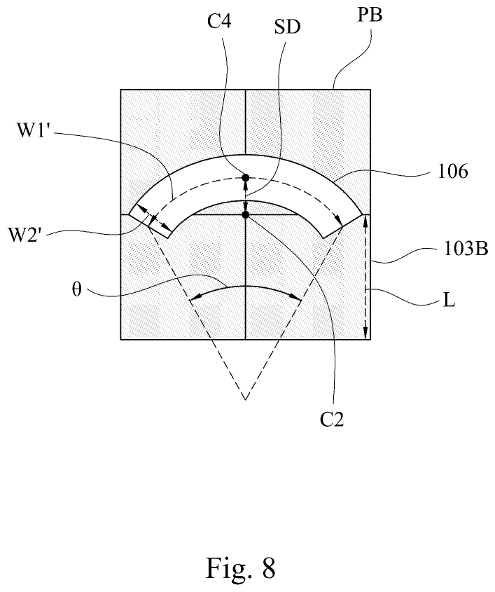

In some embodiments, the deflection elements 106 disposed in different positions of the array of pixels P may be shifted respectively to each other from a top view, such that the deflection elements 106 may align differently in the array of pixels P, as shown in FIGS. 4 to 5 and FIGS. 7 to 8, in which FIG. 5 and FIG. 8 are enlarged views of one of the PDAF pixels PB shown in FIG. 4 and one of the PDAF pixels PB shown in FIG. 7, respectively. In some embodiments, in each of the PDAF pixels PB from a top view, a shifted distance SD is between the geometric center C4 of the deflection element 106 and the center C2 of the PDAF pixel PB. By shifting the deflection elements 106, the incoming light may effectively irradiate the photoelectric conversion elements 103 and the mismatch of the sensing between the PDAF pixels PB and the sensing pixels PA may be corrected for a better sensing quality. In some embodiments, the shifted distance SD is preferably equal to X*ND+Y, where X is from 0 to ½ times a length L of one of the four photoelectric conversion elements 103B, Y is from − 1/30 to 1/30 times the length L of the one of the four photoelectric conversion elements 103B, and ND is equal to D/D_{MAX}. D is a distance R2 between the center C2 of the PDAF pixel PB and the center C1 of the array of pixels P, and D_{MAX} is a distance R1 between the center C1 of the array of pixels P and an edge E of the array of pixels P farthest away from the center C1 of the array of pixels P. Therefore, since ND is from 0 to 1 and has a positive linear relationship with the distance R2, the shifted distances SD of the PDAF pixels PB may be different depending on the positions of the PDAF pixels PB in the array of pixels P. In addition to the shifted distances SD may be different, the deflection element 106 may shift in a direction DIR1 toward the center C1 of the array of pixels P or in a direction DIR2 away from the center C1 of the array of pixels P depending on the positions of the PDAF pixels PB in the array of pixels P. For example, when the PDAF pixels PB include a PDAF pixel PB9 and a PDAF pixel PB10, and the PDAF pixel PB9 is closer to the center C1 of the array of pixels P than the PDAF pixel PB10, the geometric center C4 of the deflection element 106 of the PDAF PB9 pixel may shift from the center C2 of the PDAF pixel PB9 in the direction DIR1 toward the center C1 of the array of pixels P, and the geometric center C4 of the deflection element 106 of the PDAF pixel PB10 may shift from the center C2 of the PDAF pixel PB10 in the direction DIR2 away from the center C1 of the array of pixels P. In some embodiments, the length L of the one of the four photoelectric conversion elements 103B is preferably from 0.25 μm to 4 μm. for example, 0.25 μm, 0.5 μm, 0.75 μm, 1 μm, 1.5 μm, 2 μm, 2.5 μm, 3 μm, 3.5 μm, or 4 μm. In some embodiments, each of the four photoelectric conversion elements 103B is a square from a top view, such that the length L may correspond to either side of the square. In some embodiments, the shifted distance SD is larger than 0 for the PDAF pixel PB disposed on the edge of the array of pixels P. In some embodiments, the deflection elements 106 are shifted such that the deflection elements 106 are arranged in a centrosymmetric pattern, and the center of the centrosymmetric pattern corresponds to the center C1 of the array of pixels P.

More details of the deflection elements 106 are provided. The deflection elements 106 described above may have different shapes. In the first embodiment shown in FIGS. 3 to 5, each of the deflection elements 106 has a rectangle shape from a top view, and the rectangle shape has a long side LS and a short side SS that is shorter than the long side LS. In the first embodiment, the long side LS is arranged to face the center C1 of the array of pixels P from a top view. In the first embodiment, a length W1 of the long side LS is preferably from 0.5 μm to 4 μm, for example, 0.5 μm, 0.75 μm, 1 μm, 1.5 μm, 2 μm, 2.5 μm, 3 μm, 3.5 μm, or 4 μm. In the first embodiment, a length W2 of the short side SS is preferably from 0.1 μm to 0.5 μm, for example, 0.1 μm, 0.2 μm, 0.3 μm, 0.4 μm, or 0.5 μm. In the first embodiment, a ratio of the length W1 to the length L of either one of the four photoelectric conversion elements 103B is preferably from 1 to 2, for example, 1, 1.25, 1.5, 1.75, or 2. In the second embodiment shown in FIGS. 6 to 8, each of the deflection elements 106 has an arc shape from a top view, and an arc angle θ of the arc shape is larger than or equal to 90° and is smaller than 180°. In the second embodiment, a concave side CS of the arc shape is arranged to face the center C1 of the array of pixels P from a top view. In the second embodiment, a length w1′ (or an arc length) of the deflection element 106 is preferably from 0.5 μm to 4 μm, for example, 0.5 μm, 0.75 μm, 1 μm, 1.5 μm, 2 μm, 2.5 μm, 3 μm, 3.5 μm, or 4 μm. In the second embodiment, a length w2′ of the deflection element 106 from one end of the curvature to the other end of the curvature is preferably from 0.1 μm to 0.5 μm, for example, 0.1 μm, 0.2 μm, 0.3 μm, 0.4 μm, or 0.5 μm. In the second embodiment, a ratio of the length W1′ to the length L of either one of the four photoelectric conversion elements 103B is preferably from 1 to 2, for example, 1, 1.25, 1.5, 1.75, or 2.

The imaging device of the present disclosure significantly improves the sensitivity of the phase detection auto focus (PDAF) pixels to perform the phase detection, thereby improving the efficiency and the accuracy of performing autofocusing by the imaging device. In addition, excellent sensing quality is achieved by the imaging device of the present disclosure, such as compensating for the sensing mismatch between the PDAF pixels and the rest of the pixels, maintaining high resolution of sensing, avoiding shading and color mismatch, increasing sensing intensity, etc.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. An imaging device, comprising:
a substrate having an isolation region;
an array of pixels, comprising a plurality of sensing pixels and a plurality of phase detection auto focus (PDAF) pixels, wherein each of the PDAF pixels comprises:
four photoelectric conversion elements in the substrate and separated by the isolation region of the substrate;
a color filter layer on the four photoelectric conversion elements; and
a deflection element inside the color filter layer and partially over the isolation region of the substrate, wherein a refractive index of the deflection element is larger than a refractive index of the color filter layer.

2. The imaging device of claim 1, wherein the refractive index of the deflection element is from 1.5 to 2.0.

3. The imaging device of claim 1, wherein a ratio of a number of the PDAF pixels to a number of the sensing pixels in the array of the pixels is from 0.8% to 1.64%.

4. The imaging device of claim 1, wherein from a cross-section view, a height of the deflection element is smaller than ⅓ of a height of the color filter layer.

5. The imaging device of claim 4, wherein the height of the deflection element is from 0.15 μm to 0.3 μm.

6. The imaging device of claim 1, wherein:
from a top view, an array axis extends from a center of the array of pixels to a short side of the array of pixels and the array axis is parallel to a long side of the array of pixels; and
for each of the PDAF pixels, a first connection line is defined to connect a center of the PDAF pixel to the center of the array of pixels, a position angle is between the array axis and the first connection line, a pixel axis passes the center of the PDAF pixel and is parallel to the array axis, a second connection line is defined to connect centers of two farthest sides of the deflection element, an angle is between the pixel axis and the second connection line, and the angle is equal to 90° minus the position angle.

7. The imaging device of claim 1, wherein from a top view, the array of pixels has a positive X-axis, a positive Y-axis, a negative X-axis, and a negative Y-axis corresponding to a Cartesian coordinate, an origin of the Cartesian coordinate is at a center of the array of pixels, the PDAF pixels comprise a first PDAF pixel on the positive X-axis, a second PDAF pixel on the positive Y-axis, a third PDAF pixel on the negative X-axis, and a fourth PDAF pixel on the negative Y-axis, and relative to the deflection element of the first PDAF pixel, the deflection element of the second PDAF pixel, the deflection element of the third PDAF pixel, and the deflection element of the fourth PDAF pixel are rotated 90°, 180°, and 270°, respectively.

8. The imaging device of claim 7, wherein the PDAF pixels further comprise a fifth PDAF pixel on a diagonal line between the positive X-axis and the positive Y-axis, a sixth PDAF pixel on a diagonal line between the positive Y-axis and the negative X-axis, a seventh PDAF pixel on a diagonal line between the negative X-axis and the negative Y-axis, and an eighth PDAF pixel on a diagonal line between the negative Y-axis and the positive X-axis, and relative to the deflection element of the first PDAF pixel, the deflection element of the fifth PDAF pixel, the deflection element of the sixth PDAF pixel, the deflection element of the seventh PDAF pixel, and the deflection element of the eighth PDAF pixel are rotated 45°, 135°, 225°, and 315°, respectively.

9. The imaging device of claim 1, wherein from a top view, the PDAF pixels comprise a first PDAF pixel and a second PDAF pixel, the first PDAF pixel is closer to a center of the array of pixels than the second PDAF pixel, a center of the deflection element of the first PDAF pixel shifts from a center of the first PDAF pixel in a direction toward the center of the array of pixels, and a center of the deflection element of the second PDAF pixel shifts from a center of the second PDAF pixel in a direction away from the center of the array of pixels.

10. The imaging device of claim 1, wherein in each of the PDAF pixels from a top view, a shifted distance is between a center of the deflection element and a center of the PDAF pixel, and the shifted distance is equal to X*ND+Y, where X is from 0 to ½ times a length of one of the four photoelectric conversion elements, Y is from − 1/30 to 1/30 times the length of the one of the four photoelectric conversion elements, ND is equal to D/D_{MAX}, D is a distance between the center of the PDAF pixel and a center of the array of pixels, and D_{MAX} is a distance between the center of the array of pixels and an edge of the array of pixels that is farthest away from the center of the array of pixels.

11. The imaging device of claim 10, wherein the length of the one of the four photoelectric conversion elements is from 0.25 μm to 4 μm.

12. The imaging device of claim 1, wherein the deflection element has a rectangle shape from a top view, and the rectangle shape has a long side and a short side that is shorter than the long side.

13. The imaging device of claim 12, wherein the long side is arranged to face a center of the array of pixels from the top view.

14. The imaging device of claim 12, wherein a length of the short side is from 0.1 μm to 0.5 μm, and a length of the long side is from 0.5 μm to 4 μm.

15. The imaging device of claim 1, wherein the deflection element has an arc shape from a top view, and an arc angle of the arc shape is larger than or equal to 90° and is smaller than 180°.

16. The imaging device of claim 15, wherein a concave side of the arc shape is arranged to face a center of the array of pixels from the top view.

17. The imaging device of claim 1, wherein the deflection element comprises TiO₂.

18. The imaging device of claim 1, wherein each of the PDAF pixels is surrounded by the sensing pixels, and the deflection element is not configured in the sensing pixels.

19. The imaging device of claim 1, wherein an upper surface of the deflection element is in direct contact with the color filter layer.

20. The imaging device of claim 1, wherein each of the PDAF pixels further comprises a light converging element, and in each of the PDAF pixels, a center of the light converging element shifts from a center of the PDAF pixel.
